(19) United States
(12) Patent Application Publication
(10) Pub. No.: US 2008/0138581 A1
(43) Pub. Date: Jun. 12, 2008

(54) Masking high-aspect aspect ratio structures

(76) Inventors: Rajmohan Bhandari, Salt Lake City, UT (US); Sandeep Negi, Salt Lake City, UT (US); Florian Solzbacher, Salt Lake City, UT (US); Richard Normann, Park City, UT (US)

Correspondence Address: THORPE NORTH & WESTERN, LLP., P.O. Box 1219, SANDY, UT, 84091-1219, US

(21) Appl. No.: 11/807,763

(22) Filed: May 29, 2007

Related U.S. Application Data
(60) Provisional application No. 60/831,557, filed on Jul. 17, 2006.

(51) Int. Cl. G03F 7/00; B32B 3/00

(52) U.S. Cl. 428/156; 430/313

(57) ABSTRACT

A method of masking high-aspect ratio structures on a wafer includes submerging the wafer in a resist material so that the high-aspect ratio structures are at least partially embedded within the resist material. The resist material is cured and further processing steps, such as for example oxygen plasma etching, are applied, for example to remove portions of the resist material and material from upper portions of the high-aspect ratio structures.

### RELATED APPLICATIONS

This application claims the benefit of and hereby incorporates by reference U.S. Provisional Patent Application Ser. No. 60/831,557, filed Jul. 17, 2006, and entitled “An Integrated Wireless Neural Interface for Chronic Recording and Stimulation.” This application is also related to concurrently filed U.S. patent application Ser. No. N/A, entitled “WAFER SCALE NEEDLE ARRAY” (attorney docket number 00846-U4192.NP) and concurrently filed U.S. patent application Ser. No. N/A, entitled “MICRO-NEEDLE ARRAYS HAVING NON-PLANAR TIPS AND METHODS OF MANUFACTURE THEREOF” (attorney docket number 00846-U4203.NP), each of which is hereby incorporated by reference.

### GOVERNMENT RIGHTS

This invention was made with government support by the National Institutes of Health under Contract No. HHSN265200423621C and the Defense Advanced Research Projects Agency under Award No. 908164. The government has certain rights to this invention.

### BACKGROUND

1. Field of the Invention

The present invention relates generally to masking of high-aspect ratio structures on a wafer.

2. Related Art

A variety of complex structures can be fabricated on wafers using micromachining techniques. Examples include micro-electrical-mechanical systems (MEMS) and micro-needle arrays (e.g., the Utah Electrode Array).

One challenge in micromachining is applying processing to high-aspect ratio structures on a wafer. Conventional lithographic techniques (e.g., for semiconductor device fabrication) are typically performed on relatively planar surfaces. For example, photolithography involves coating a wafer with a photo resist, exposing the photo resist through a mask to illuminate patterns on the photo resist, developing the photo resist to remove either exposed (positive photo resist) or unexposed (negative photo resist) portions, and then applying further processing steps to the wafer portions that have been revealed. When high-aspect ratio structures are present, it can be difficult to obtain a uniform coating over the structures. In particular, pooling of photo resist in deep trenches and lack of coverage of elevated structures can occur.

As a particular example, the Utah Electrode Array (UEA) provides an example of a very high-aspect ratio structure. The UEA is a regular array of silicon micro-needles extending approximately 1.5 mm from a substrate. During fabrication of the UEA, it is sometimes desired to perform certain processing steps to the tip portions of the array only. Accordingly, it is desired to provide a way to mask all but the end 20 to 100 micrometers of the micro-needles. Traditionally, the mask has been implemented by poking the tips of the UEA through an aluminum foil mask. While somewhat effective, this approach is manually intensive and can result in large non-uniformity of tip exposure.

### SUMMARY

Briefly, and in general terms, the invention is directed to methods of masking high-aspect ratio structures on a wafer. In one embodiment, the method can include submerging the wafer in a resist material so that the high-aspect ratio structures are embedded within the resist material. The material can be cured, and a processing step applied to the wafer.

### BRIEF DESCRIPTION OF THE DRAWINGS

Additional features and advantages of the invention will be apparent from the detailed description which follows, taken in conjunction with the accompanying drawings, which together illustrate, by way of example, features of the invention; and, wherein:

FIG. 1 (a)-1(d) is a series of side view illustrations of a method of masking a high-aspect ratio structure in accordance with an embodiment of the present invention, FIG. 1(a) is a micro-needle array, FIG. 1(b) is the micro-needle array submerged in photo resist, FIG. 1(c) shows the tips of the micro-needles undergoing plasma etching, and FIG. 1(d) shows the micro-needle array after stripping of the resist material showing a portion of the coating removed from the micro-needles;

FIG. 2 is a side view illustration of a high-aspect ratio structure being processed with a positive photo resist;

FIG. 3 is a side view illustration of a high-aspect ratio structure being processed with a negative photo resist; and

FIG. 4 is a side view illustration of a micro-needle array having tips disposed in a non-planar surface and masked using a photo resist that conforms to the non-planar surface.

### DETAILED DESCRIPTION OF EXAMPLE EMBODIMENT(S)

In describing embodiments of the present invention, the following terminology will be used.

The singular forms “a,” “an,” and “the” include plural referents unless the context clearly dictates otherwise. Thus, for example, reference to “a needle” includes reference to one or more of such needles and “exposing” or “etching” includes reference to one or more of such steps.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “50-250 micrometers should be interpreted to include not only the explicitly recited values of about 50 micrometers and 250 micrometers, but also include individual values and sub-ranges within the indicated range. Thus, included in this numerical range are individual values such as 60, 70, and 80 micrometers, and sub-ranges such as from 50-100 micrometers, from 100-200, and from 100-250 micrometers, etc. This same principle applies to ranges reciting only one numerical value and should apply regardless of the breadth of the range or the characteristics being described.

As used herein, the term “about” means that dimensions, sizes, formulations, parameters, shapes and other quantities and characteristics are not and need not be exact, but may be approximated and/or larger or smaller, as desired, reflecting tolerances, conversion factors, rounding off, measurement error and the like and other factors known to those of skill in the art. Further, unless otherwise stated, the term “about” shall expressly include “exactly,” consistent with the discussion above regarding ranges and numerical data.

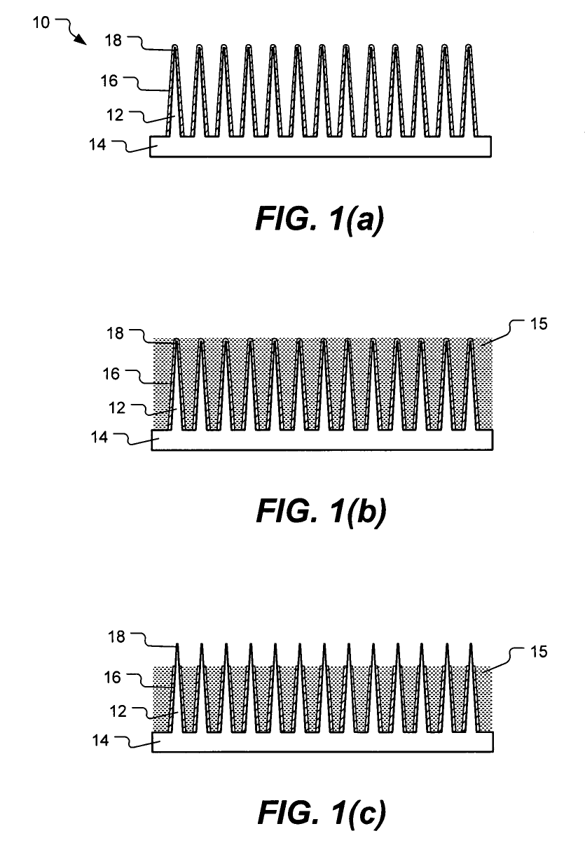

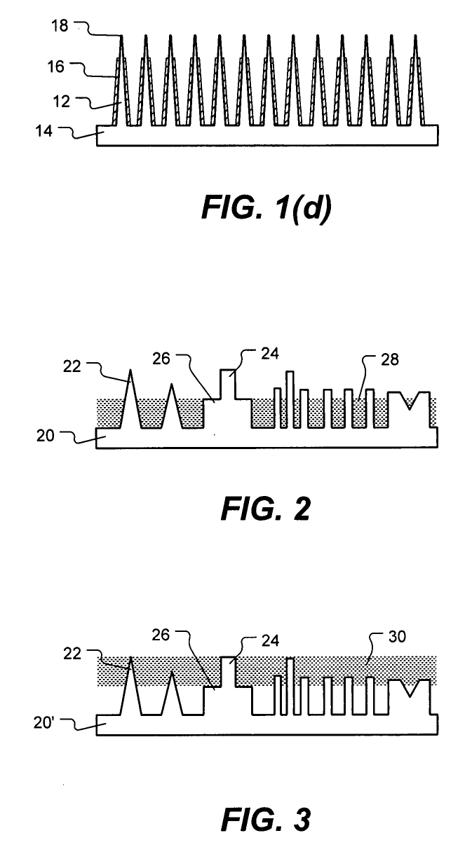

A method of masking high-aspect ratio structures will be described with reference to a micro-needle array as illustrated in FIG. 1(a). For example, co-pending U.S. patent application Ser. No. N/A, entitled “WAFER SCALE NEEDLE ARRAY” (attorney docket number 00846-U4192.NP) describes a micro-needle array which can be processed by the techniques disclosed herein. It will be appreciated, however, that embodiments of the presently disclosed methods can be applied to other high-aspect ratio geometries.

The micro-needle array 10, includes a plurality of high-aspect ratio structures in the form of micro-needles 12 extending upward from the wafer 14. The micro-needles can optionally include a coating 16. In one aspect, this coating can be an insulating material such as, but not limited to, parylene-C, silicon carbide, ceramics, or other insulating polymers. The method of the present invention includes submerging the wafer in a resist material so that the high-aspect ratio structures are at least partially embedded within the resist material 15 as shown in FIG. 1(b). For example, the high-aspect ratio structures may be entirely embedded within the resist material.

The resist material may be spin coated onto the wafer using relatively low revolution rates of about 100-500 revolutions per minute (rpm) as compared to conventional spin rates of 2000-3000 rpm used in semiconductor device fabrication. The spin rate should be sufficiently low to embed the structures in the resist while also providing a sufficiently uniform coverage of resists across the wafer. When coating the wafer, it is helpful to place the wafer into a recessed holder, the depth of the recess being sufficient to contain the level of resist material to be placed on the wafer. For example, a wafer having high-aspect ratio structures extending about 1.5 mm in height may be placed in a holder having a recess of depth in excess of 1.5 mm to ensure that the structures can be completely submerged.

The resist material can be cured, for example by baking. Before curing, the wafer may be optionally placed into a vacuum (e.g., pressure less than about 10⁻² torr) to encourage bubble elimination from the resist material.

A further processing step is then applied to the wafer. For example, the further processing step may be plasma etching, wet etching, vapor deposition, sputtering, laser ablation, or similar operations or combinations thereof.

As a particular example, the further processing step may be oxygen plasma etching. As shown in FIG. 1(c), the oxygen plasma etching removes the resist material starting at the tips 18, and as the tips are exposed, removes the coating 16 (if present) from the tips as well. The amount of etching time determines the amount of exposure of the tips and removal of the coating. Thus, in this embodiment, the tips are deencapsulated during the same step as removal of the resist material.

As another example, laser ablation (e.g. using an excimer laser) can be used to remove coatings, both at array and wafer scale level. Under suitable conditions, parylene-C encapsulation may be completely ablated from the tip while an underlying metal coating remains substantially un-ablated. The energy output of the laser (E), aperture size (d), de-magnification (D), and number of pulses (n), and transmission (%) all effect the process. For example, for E equal to 4 mJ, transmission equal to 75%, D equal to 10, d equal to 0.2 mm and n equal to 23 it was possible to remove parylene-C from a microscopic needle array without ablating the metal coating. Laser ablation may be particularly helpful when a non-planar geometry is present to the high-aspect ratio structures.

Following the further processing step, the remaining resist material may then be stripped from the wafer, as shown in FIG. 1(d).

In accordance with another embodiment, the resist material may be a photo resist material. For example, the photo resist material may be a positive photo resist or a negative photo resist. After the wafer is submerged in photo resist material, the photo resist material may be dried (e.g., soft baked). If desired, the photo resist material may be exposed to a vacuum to encourage bubble elimination before drying.

A top layer of the photo resist material may then be exposed to a light source (e.g. infrared, visible or ultraviolet light). The photo resist material can then be developed by immersion in a developer solution to remove exposed portions (positive photo resist) or to remove unexposed portions (negative photo resist).

For example, a positive photo resist will be removed to expose upper portions of the high-aspect ratio structures. FIG. 2 illustrates a wafer 20 having high-aspect ratio structures 22 which have upper portions 24 exposed after developing while lower portions 26 remain embedded within the positive photo resist 28. Note that the high-aspect ratio structures may present varying shapes and heights.

Conversely, as shown in FIG. 3, a negative photo resist 30 will be removed from the wafer 20 to expose lower portions 26 of the high-aspect ratio structures 22 while upper portions 24 remain embedded within the negative photo resist.

Further processing steps can then be applied to affect the upper portions 24 or lower portions 26 of the high-aspect ratio structures such as those described previously.

If desired, processing can be repeated using both positive and negative photo resists to provide more control and complexity in the vertical dimension. Also, various patterns may also be exposed into the photo resist, for example, to leave/remove photo resist in only certain portions of the wafer.

One advantage of the above described techniques is that the upper portions of the high-aspect ratio structures need not be planar. For example, as described in co-pending U.S. patent application Ser. No. N/A, entitled “MICRO-NEEDLE ARRAYS HAVING NON-PLANAR TIPS AND METHODS OF MANUFACTURE THEREOF” (attorney docket number 00846-U4203.NP) a micro-needle array can have micro-needle tips disposed in a non-planar surface. It has been observed that surface tension of the resist material helps the upper surface of the resist material to conform to nearly any curvature of the top of the high-aspect ratio structures.

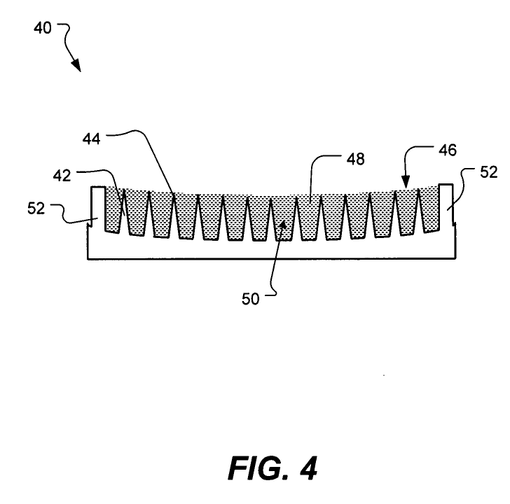

For example, FIG. 4 illustrates a micro-needle array 40 having micro-needles 42 with tips 44 disposed in a non-planar surface 46. The photo resist 48 fills the area 50 between the micro needles, and surface tension of the photo resist helps to conform the photo resist to the non-planar surface.

The conforming of the photo resist to the top layer of the high-aspect ratio structures can be further enhanced by including sacrificial features, such as fins or posts positioned to control contouring of the top layer of the positive photo resist material. In particular, the inclusion of fins 52 or posts at the edges of the micro-needle array 40 can help to conform the photo resist to the non-planar surface. Accordingly, when etching is performed, the length of etching is substantially constant relative to the tip length, rather than being a fixed height.

The above described processes have been used in the manufacturing of micro-needle arrays to provide for de-encapsulation of planar-disposed and non-planar-disposed micro-needle tips. The amount of de-encapsulation can be controlled by the length of light exposure, the time duration of etching, or a combination of both variables. The micro-needle arrays include silicon micro-needles, over which there is a metal coating, encapsulated in parylene-C. The tips of the micro-needles are de-encapsulated as described above. De-encapsulation lengths of about 20 micrometers, plus or minus 10 micrometers have been obtained on planar arrays, and about 100 micrometers, plus or minus 50 micrometers have been obtained on non-planar arrays. In contrast, the previous aluminum foil masking technique provided about 100 micrometers of de-encapsulation plus or minus 50 micrometers on planar arrays only and required processing each array individually. Further, masking using an aluminum foil on such small features having a contoured tip surface does not appear to be feasible or even possible. As a general matter, the methods of the present invention can allow for de-encapsulation lengths in planar arrays of from about 15 micrometers to about 50 micrometers with variations less than about 10 microns. Similarly, uniformity on non-planar arrays can allow for de-encapsulation lengths from about 80 to about 150 micrometers with variations less than about 50 micrometers. However, it will be understood that using the methods of the present invention may also allow for further improved tolerances based on additional routine testing using the disclosure herein.

Accordingly, the disclosed methods can provide substantially improved consistency in the tolerance of tip de-encapsulation and similar processing steps. Reduced processing time can be obtained because an entire wafer can be processed simultaneously. High throughput, repeatability, and reducing handling of the wafers are therefore provided.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention.

1. A method of masking high-aspect ratio structures on a wafer comprising:
submerging the wafer in a resist material so that the high-aspect ratio structures are at least partially embedded within the resist material;
curing the resist material; and
applying a further processing step to the wafer.

2. The method of claim 1, further comprising placing the wafer into a receptacle of sufficient depth to contain the resist material to a desired level.

3. The method of claim 1, further comprising placing the wafer in a vacuum to encourage bubble elimination from the resist material.

4. The method of claim 1, further comprising stripping the resist material from the wafer.

5. The method of claim 1, wherein the resist is a positive photo resist material and further comprising, before curing the photo resist material:
drying the positive photo resist material;
exposing the top layer of the positive photo resist material to a light source; and
removing the top layer of the positive photo resist material to reveal upper portions of the high-aspect ratio structures while remaining photo resist material covers lower portions of the high-aspect ratio structures.

6. The method of claim 5, wherein the upper portions of the high-aspect ratio structures define a non-planar surface to which the top layer of the positive photo resist conforms.

7. The method of claim 1, wherein the resist is a negative photo resist material and further comprising, before curing the photo resist material:
drying the negative photo resist material;
exposing the top layer of the negative photo resist material to a light source; and
removing the negative photo resist material to reveal lower portions of the high-aspect ratio structures while remaining photo resist material covers upper portions of the high-aspect ratio structures.

8. The method of claim 7, wherein the upper portions of the high-aspect ratio structures define a non-planar surface to which the top layer of the negative photo resist conforms.

9. The method of claim 1, wherein the high-aspect ratio structures are completely submerged within the resist material.

10. The method of claim 1, wherein submerging the wafer comprises spin coating the wafer with the resist material.

11. The method of claim 1, wherein the further processing step is selected from the group consisting of plasma etching, wet etching, vapor deposition, sputtering, laser ablation, and combinations thereof.

12. The method of claim 1, wherein the further processing step comprising removing a coating previously applied to the upper portions of the high-aspect ratio structures.

13. A product formed by the process of claim 1.

14. A method of masking high-aspect ratio structures on a wafer comprising:
spin coating the wafer with a positive photo resist material until the high-aspect ratio structures are completely embedded within the positive photo resist material, a top layer of the positive photo resist material covering upper portions of the high-aspect ratio structures;
drying the positive photo resist material;
exposing the top layer of the positive photo resist material;
removing the top layer of the positive photo resist material using a developer solution to reveal the upper portions of the high-aspect ratio structures while remaining photo resist material covers lower portions of the high-aspect ratio structures;
curing the remaining positive photo resist material; and
applying a further processing step to the upper portions of the high-aspect ratio structures.

15. The method of claim 14, wherein the further processing step is oxygen plasma etching of the upper portions of the high-aspect ratio structures.

16. The method of claim 14, wherein the upper portions of the high-aspect ratio structures define a non-planar surface to which the top layer of the positive photo resist conforms thereto.

17. The method of claim 14, wherein the high-aspect ratio structures include sacrificial structures positioned to control contouring of the top layer of the positive photo resist based on surface tension of the positive photo resist.

18. A product formed by the process of claim 14.

19. A micro-needle array comprising:
a substrate;
a plurality of needles supported by the substrate;
an electrically conductive coating disposed on the plurality of needles; and
an electrically insulating coating disposed over the electrically conductive coating except on deencapsulated portions of tips of the needles, the deencapsulated portions being substantially uniform in tip length.

20. The micro-needle array of claim 19, wherein the deencapsulated portions extend less than about 50 micrometers from the tip with a tolerance within plus or minus 10 micrometers.

21. The micro-needle array of claim 19, wherein the tips of the micro-needles define a non-planar surface.

22. The micro-needle array of claim 21, wherein the deencapsulated portions extend less than about 150 micrometers from the tip with a tolerance of plus or minus 50 micrometers
